(19) United States
(12) Patent Application Publication
(10) Pub. No.: US 2010/0000165 A1
(43) Pub. Date: Jan. 7, 2010

(54) SOLAR ROOF

(76) Inventor: Alexander Koller, Freiburg (DE)

Correspondence Address: VOLPE AND KOENIG, P.C., UNITED PLAZA, SUITE 1600, 30 SOUTH 17TH STREET, PHILADELPHIA, PA, 19103, US

(21) Appl. No.: 12/439,204

(22) PCT Filed: Sep. 7, 2007
(86) PCT No.: PCT/EP2007/007831

§ 371 Date: Feb. 27, 2009

(30) Foreign Application Priority Data
Sep. 8, 2006 (DE) 10 2006 042 808.0

(51) Int. Cl. E04D 13/18; H01L 31/052

(52) U.S. Cl. 52/173.3; 136/246

(57) ABSTRACT

A solar roof (1) for roofing over an area or a built volume. The solar roof (1) comprises one or more solar modules (3) that are associated with a solar power plant, at least one reflective surface (4) which is arranged at an angle to the solar module/s, and other optional roof elements. In order to create an efficient solar roof (1) which can be used for roofing over basically any area without major adjustment difficulties while keeping costs and the mounting effort low, among other things the edge regions (5) of the solar module/s (3) are interconnected and/or connected to the reflective surface/s (4), and the solar module/s (3) and the reflective surface/s (4) are connected to optional roof elements, in such a way that the solar roof (1) forms a closed, sealed roof cladding as a continuous surface, and the solar roof (1) is a load-bearing roof structure.

### BACKGROUND

The invention relates to a solar roof for roofing over an area or a built volume, with the solar roof comprising one or more solar modules allocated to a solar power plant and at least one reflective surface arranged at an angle in reference to the solar module or modules as well as optional roof elements.

In construction and generally when roofing over areas and/or volumes increasingly modules are used, called solar or photo-voltaic modules, in order to use the areas of the roofing over the respective area and/or the volume exposed to the solar radiation for generating energy. A better yield of the sunlight, irradiating the solar module to a varying extent depending on the position of the sun, is achieved here over the entire period of the solar radiation when in addition to the collector areas of the solar modules, frequently arranged side-by-side at a distance from each other, reflective areas are used that are capable to deflect incident light to the solar modules. Such devices are known, for example, from DE 20 2005 012 798 U1, in which solar modules and reflective areas are used to cover building surfaces.

Here, it is disadvantageous in the solar devices of prior art that the solar modules and the reflective surfaces have to be subsequently adjusted to existing roof structures with considerable assembly and monetary expenses and must be arranged there. Thus, the effectiveness of the entire arrangement is restricted by some reflective areas being omitted due to the conditions on site.

### SUMMARY

Therefore, the object is to provide a solar roof with good effectiveness, which can be used without any difficult adjustments and with little monetary and assembly expenses during the production and the renovation of the roofing of fundamentally arbitrary base areas.

This object, seemingly contradictory at first, is attained in a solar roof of the type mentioned at the outset, in which the solar module or modules are interconnected and/or are connected to the reflective area or areas and both of them to optional roof elements at their edge regions such that the solar roof forms a continuous area of a closed, sealed roof cladding and the solar roof is provided as a load-bearing roof construction. Thus, the solar roof forms a statically independent support structure, with the roof cladding here also being embodied rain tight as well as water tight.

Instead of awkwardly mounting solar modules onto existing structures, the solar modules and reflective surfaces as well as optional roof elements that can be arranged at a support structure can form a sealed roof cladding for the area to be roofed over or a partial area thereof, having a completely load-bearing roof construction, which may form the upper part, for example of a building structure of either new construction or existing buildings being renovated, which can be preassembled as a closed, sealed surface or can be applied to such. In general, in all cases described a solar module may also form a reflective area so that maximally all roof areas can be formed by solar modules, for example. Exemplary areas or volumes roofed over with a potential sub-structure to be considered are, in addition to buildings in general, also the roofing and/or cladding of carports, halls, parking spaces, greenhouses, warehouses, and the like, and also areas such as swimming pools, particularly roofing structures formerly or originally designed as flat roofs. A potential roofing form considered for the roofing structure may also be the so-called shed-roof, for example, having several rows of gables. It is not necessary for the solar roof according to the invention that the solar modules and reflective areas are exclusively interconnected or connected to each other, for example intermediate spaces may also be provided made from other materials for bridging difficult roof areas, to provide recesses for windows or the like, or just allowing general roofing elements to accommodate structural, legal, or esthetic demands. Here, essential attention must be turned to areas absorbing or reflecting the solar radiation not shadowing each other, thus shadow effects are excluded to the extent possible.

In addition to the possibility of adjusting the solar modules or support areas of a solar roof according to the invention such that they essentially are self-supporting, for the roof construction thus being load-bearing, it can be beneficial for an embodiment of the solar roof that, for a better stability of the overall construction, a supporting device is arranged at a girder or the like, which at least punctually supports a section of the solar roof.

The object is also attained in a solar roof of the type mentioned at the outset in which at least one heat exchanger is provided at the solar module or modules and/or, if applicable, at the reflective area or areas, that can be connected or integrated in a detachable fashion, by which the temperature of the solar module or the reflective area can be locally changed in the area of its mounting. By a local change of the temperature at the photovoltaic modules their effectiveness can be increased by way of cooling so that a higher yield is achievable, which in turn leads to more beneficial operating costs and perhaps finally an installation or renovation of a roofing is rendered profitable for the principal. In case of heating the modular sections or the reflective areas with the heat exchanger these areas can be freed from snow covering, for example, and thus be returned more quickly to operation. Additionally, the solar roof is rendered more secure thereby, because no loads endangering the stability can accumulate on the roofing and thus it can be designed lighter, and perhaps more cost-effective thereby. The heat exchanger can be embodied fully integrated in the solar module and/or the reflective area, if necessary, it may also be provided for a detachable assembly and removal at the respective areas. The heat exchangers are preferably operated with a liquid, for example water, or another suitable chemical compound.

A beneficial embodiment of the solar roof according to the invention may comprise embodying the heat exchanger as a planar storage element arranged at the side of the solar module or the reflective area facing the base, with its preferably tight contact to the respective area over its entire surface ensuring an effective heat exchange in both directions.

A useful further embodiment may comprise that the heat exchanger is provided with an inlet and an outlet and forms a part of a particularly unpressurized storage circuit comprising a reservoir. The storage circuit in turn can feed heat guided off the areas to a heating circuit, for example.

Furthermore, the present object is also attained in a solar roof of the type mentioned at the outset in which at least one of the solar modules and/or particularly at least one of the reflective areas of the solar roof is arranged at a joint, articulate around a respectively fixed edge in the direction of a neighboring reflective surface and/or a neighboring solar module. This way, the angle of the areas exposed to the solar radiation can follow the radiation such that at all times an optimal yield of the radiation and thus an optimized profit with regard to costs can be achieved with the solar roof according to the invention. Any reduction of profit due to potential heating can here be compensated by a generally arbitrary coolant. Using mobile roofing parts, additionally a simple and cost-effective ventilation of the roofed-over volume can be achieved in a simple fashion, in particular, this also forms a so-called smoke-heat-ventilation (RWA).

In order to allow optionally influencing the alignment of the solar modules and/or reflective areas of the solar roof, either by an intermittent manual or constantly automated, controlled guidance of the mobile areas, it is advantageous in an embodiment of the solar roof if at least one potentially controlled adjuster is arranged for moving the respective roof elements in the region of mobile solar modules and/or reflective areas and/or in the region of the supporting structure.

Here, it is desirable that in spite of changing positions of mobile solar modules and/or reflective areas the roofing performs a sealing function in reference to the area it covers, thus a useful further embodiment of the solar roof comprises that in the region of the free end of the reflective area or in the edge region of the solar module neighboring the free end at least one accessory element is arranged, which out of a normal position, in which it projects into the volume roofed over, can be guided gradually and/or particularly in a telescopic fashion into one or more extended positions such that it forms a part of the roofing. The respective accessory element, in the above-mentioned normal position first resting in a state without any function, is arranged in a nondescript manner covered by the roofing, and only when needed it becomes partially or entirely a part of the closed sealed roofing after being moved into an extended position, with it being embodied, as needed or previously determined, as a solar module, reflective, or other area.

In order to mobile parts, forming gaps in the roofing parts, preventing covered objects from damage, e.g., by hail, it may be advantageous for the solar roof to be provided with at least one humidity and/or liquid sensor, determining any potential wetting of the area of the solar roof and prompting the closure of open solar modules and/or reflective areas when necessary.

Another solution of the above-mentioned object is formed by a solar roof of the type mentioned at the outset, in which at the edge regions of the solar modules and/or the reflective areas and/or additional roof elements, particularly edge areas limiting the solar roof, at least one collector is provided to collect and forward liquids moistening the roof cladding. Due to the fact that a solar roof exposed to the environment is impinged with precipitation, on the one hand, and cleaning the roofing area may be necessary, e.g., to remove soiling and snow reducing the effectiveness of the solar modules, on the other hand, it is important that for example larger amounts of rain can be fast and securely guided off the roofing and perhaps additional material can be entrained without any major expense and thus cost-effectively.

Here, preferably the collector can be formed by a web of grooves crisscrossing the roofing and declining towards the drainage points, which allows the transportation of the liquid.

A supporting device of the solar roof, for example in the form of a support structure formed by a trestle or a frame, on the one hand can directly be placed upon an existing structure such as a building or can itself represent the support structure, or in another embodiment of the solar roof it can be provided with one or more supporting means, particularly tubes or similar hollow profiles, which support the support structure from another structure, for example the ground of a landscape. Furthermore, other supporting means can be provided facilitating the arrangement of the solar roof.

Advantageously, particularly in case the solar roof is provided with the collector for liquids, drainage points can be arranged at the ends of the supporting means facing the solar roof. This way, the amounts of liquids accepted by the collector can easily be transferred to supports with a hollow profile, through which the further transportation of the liquids towards the ground or another, usually larger reservoir is facilitated without requiring any additional installations in the form of drainage gutters at the support structure or other sections of a building.

Any re-supply of the collected and stored amounts of liquid to the solar roof is achieved in a beneficial further embodiment of the solar roof in that a distribution system is provided thereat, particularly at one or more ridges or eaves of gables or the gable to feed liquids perhaps existing, for example in the form of a sprinkler or irrigation system, if applicable with respective connectors and supply lines.

A useful further embodiment of the solar roof can additionally be formed such that the collector is provided with a connection to the storage circuit of the heat exchanging liquid and/or the distribution system, because this way the collected liquid can be fed to the respective storage circuit when needed and can be used as the heat exchanging liquid, or it can be used for irrigation.

In a beneficial further embodiment the solar roof is provided with a controller, which controls the supply of power generated by the solar modules into a power grid and/or the drain of power from a power grid. For this purpose, the controller can be provided with an inverter allowing it to power the solar modules. The heat created by powering the solar modules can be used in turn to prevent or remove shadowing formed by snow or the load upon the modules developing by ice formation.

In another embodiment of the solar roof according to the invention several solar modules and/or reflective areas can be connected to each other in an angular fashion and particularly form the primary area of a gable or a ridge of the solar roof, so that the radiation of solar light from different sides upon the respective gable, for example by the morning and the evening sun, can be used optimally (even) when coming from different directions.

Particularly larger areas to be covered can be well roofed over with an embodiment of the solar roof according to the invention in which the roof cladding is formed by alternating interconnected areas of solar modules and reflective areas, preferably each formed with an identical incline in reference to the base, so that the solar modules and the reflective areas each extend parallel in reference to each other and a regular sequence of gables develops.

Another embodiment of the solar roof according to the invention advantageously uses an area available from a pitched roof area of a gable for energy generation by covering the predominant part of the respective diagonal roof side with a series and/or a sequence of ridges or gabled roofs of solar modules and reflective areas connected to each other at an angle and forming gables. The alignment of the ridges of the gables of the sequence is here not mandatorily predetermined and can follow the position of the sun over the course of the day when the roof construction is designed. Such a construction is particularly beneficial when used for renovating a roof area or the cladding over existing roofing and uses the chimney-effect developing under the solar roof by rear ventilation and/or a “roof-on-roof”-construction, resulting in the solar modules, due to their temperature-dependent performance, achieving a better effectiveness.

Here, a further embodiment of the solar roof is particularly preferred in which the ridges of the sequence of areas extend essentially perpendicular in reference to the ridges of the roof gables, in a planar view, so that the position of the solar module is not predetermined by the alignment of the ridges of a gabled roof extending in the east-west direction, for example, but the modules here being inclined in reference to the gable area, initially aligned parallel for example, and this way can better utilize the changing solar radiation.

A multitude of technical and design possibilities for the embodiment of the solar roof result when using an embodiment thereof in which the solar modules and/or the reflective areas comprise elements (made from) transparent, partially transparent, and/or entirely reflective materials, particularly a glass material so that for example a space located below one or more of the respective areas can be partially or entirely irradiated by daylight and thus other lighting can be waived partially or entirely.

Particularly in residential buildings, using solar light via the solar roof according to the invention for generating power and/or heating water, the energy yielded by the building is further improved when additional insulating measures are taken preventing the dissipation of heat. Therefore, in a further embodiment of the solar roof according to the invention an insulating medium, particularly heat insulation, can be beneficially arranged between the solar modules and/or the reflective areas and the volumes roofed over. In addition to the use as building insulation the insulation medium can also be used for insulating a heat exchanger perhaps arranged at a solar module or a reflective area.

Finally, the above-mentioned object is also attained in a solar roof, perhaps of independent inventive importance, for roofing over e.g., an area or a built volume, with the solar roof being provided with one or more planar solar modules, allocated to a solar energy plant, and with at least one reflective area allocated to the solar module or modules in an angular fashion, as well as optional roof elements, in which the solar modules and/or the reflective areas can be adjusted longitudinally, particularly in a telescopic fashion, and the solar roof in its entirety therefore being able to cover both the build volume as well as covered areas of varying sizes, with the respective solar roof then not necessarily forming a closed cladding. Similarly, the respective piece of a solar module or a reflective area perhaps added by a change in length is not required to have the same consistency as the base parts to which it is added, but it can also comprise the features of the respectively other area or a completely different one.

This solar roof as well as the different above-mentioned embodiments and further developments can be used in a particularly flexible manner and can be adjusted to areas and/or roofing of volumes of various planar extent when the solar roof is adjustable to various sizes of a base area at least in one direction of extension.

### BRIEF DESCRIPTION OF THE DRAWINGS

In the following, the present invention is explained in detail using exemplary embodiments shown in the figures of the drawings. Shown here, in a partially schematic illustration:

FIG. 1 is a cross-sectional view of a portion of a first embodiment of the solar roof in form of a gabled roof with solar modules;

FIG. 2 is a cross-sectional view of a portion of a different embodiment of the solar roof to cover a flat roof, with the gable alternating being formed by solar modules and reflective areas;

FIG. 3 is a cross-sectional view of an area of another embodiment of the solar roof as a cover over a flat roof, in which solar modules and reflective areas are allocated to a common gable;

FIGS. 4a, b are cross-sectional views of an area of an embodiment of the solar roof with areas mobile at a joint, tracking integrated in the solar device;

FIG. 5 is a cross-sectional view of an exemplary embodiment of a solar roof embodied as a car port;

FIG. 6 is a perspective side view of the solar roof of FIG. 5;

FIGS. 7a, b are cross-sectional views of two positions of a solar roof with solar modules and reflective areas that can be changed in their length and telescopically;

FIG. 8 is a cross-sectional side view of a solar module with a heat exchanger arranged thereat as well as an insulating layer;

FIG. 9 is a cross-sectional side view of an exemplary embodiment of the solar roof with solar modules of FIG. 8 and reflective areas

FIGS. 10a, b are cross-sectional side views of an exemplary embodiment of the solar roof with reflective areas pivotal around joints in a closed and an open position; and

FIG. 11 is a perspective view of an exemplary embodiment of the solar roof as a roofing over an area with a schematically indicated possibility for reverse flow.

### DETAILED DESCRIPTION OF THE PREFERRED EMBODIMENTS

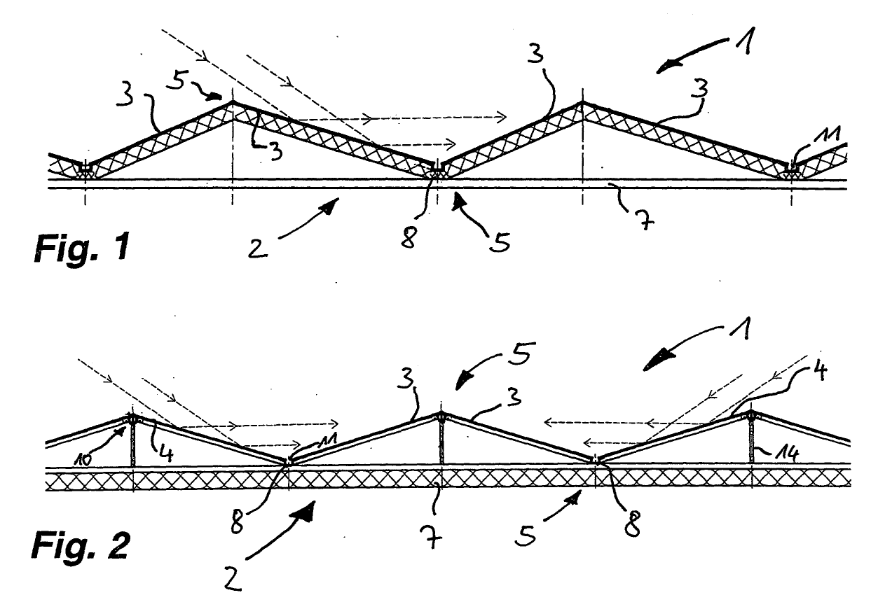

In FIG. 1 an area of the solar roof, noted as 1 in its entirety, is discernible covering an area or a built volume, with the solar roof 1 extending from the viewing plane. The solar roof 1 is arranged on a girder-type support arrangement 2, and with several planar solar modules 3, each forming a diagonal roof area, allocated to a solar power plant, not shown in greater detail. Additionally the solar roof 1 is provided with reflective areas 4, in this case embodied as solar modules 3. At the girder 2 the solar modules 3 are connected to each other in two opposite edge regions 5 such that a closed sealed cladding develops. Furthermore it is discernible that rays of sunlight, indicated by dot-dash lined arrows, irradiate a solar module 3, with their light being deflected in the direction of neighboring, opposite located solar modules 3. A cladding is formed by the solar modules 3, comprising interconnected areas of solar modules of the same incline in reference to a base area, with the solar modules 3 forming a load-bearing, i.e. a self-supporting roof, which is supported by rafters 7 of the girder system 2 in the area of the connecting sites 8 of solar modules 3 and reflective areas 4.

On the other hand, FIG. 2 shows a view of an embodiment of the solar roof 1, particularly for the use in a roof aligned in the north-south direction, in which several solar modules 3 are connected to each other at an angle and form a gable. The solar radiation, again indicated by dot-dash lined arrows, here represents different solar positions of the day and is deflected by reflective areas 4 to solar modules 3, with here the solar modules 3, shown in the center of the figure, being allocated to a common gable. Here, the solar modules 3 and the reflective areas 4 form closed, sealed roof cladding, however it is placed upon a load-bearing flat roof structure, indicated by the shaded rafters, and is not self-supporting in this case.

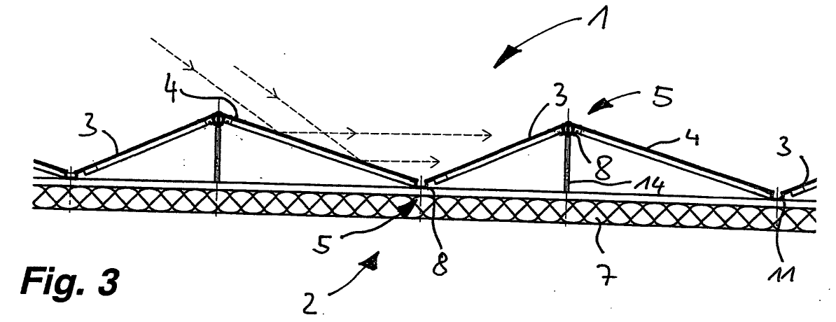

FIG. 3 also shows a nonstructural gable design of the roofing of the solar roof 1, with here in the lateral extension from the left to the right, alternating a solar module 3 and a reflective area 4 and then again another solar module 3 being connected, and so on, so that gables form from an alternating sequence of solar modules 3 and reflective areas 4 on a load-bearing flat structure, indicated by the rafters 7. In the longitudinal extension, seen in the plane of the viewer, three additional solar modules 3 are each arranged in line with the solar modules 3 and at the reflective areas 4 additional reflective areas 4 such that in the longitudinal extension of the solar roof 1 connected gable areas of solar modules 3 and reflective areas 4 each develop, inclined in reference to the covered area, not shown. The arrangement of the support elements 14 below the gables and connected to the girder 2 is common in FIGS. 3 and 2.

Further, all solar roofs 1 shown in the figures (have in common) that in the edge regions 5, in which the solar modules 3 and/or the reflective areas 4 are connected to each other, connection sites 8 are arranged, at which collectors 11 and/or in the case of joint-mobile solar modules 3 joint areas 6 can be located and/or reflective areas 4.

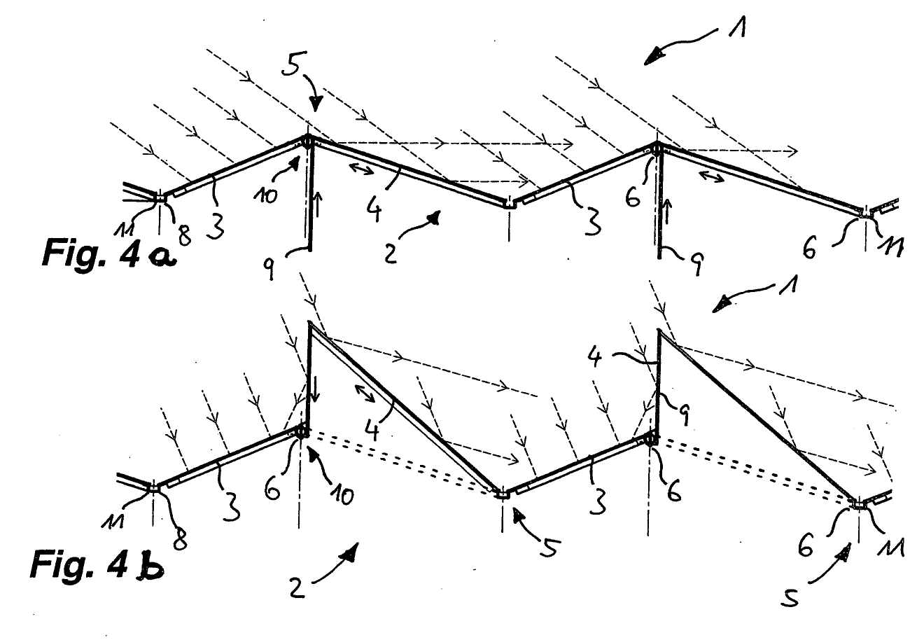

FIGS. 4a and 4b once more show a solar roof 1 with an alternating sequence of solar modules 3 and reflective areas 4, in which joints 6 are arranged in the gables of the solar roof 1 at connection sites 8 in the edge region 5. Additionally, an adjuster 10 is located there, not shown in greater detail, for example in the form of an electric motor, which transfer attachment elements 9 from a normal position shown in FIG. 4a, in which the attachment elements 9 project into the covered volume, gradually into a position shown in FIG. 4b such that they form a part of the roof cladding. For this purpose, additionally, the reflective areas 4 are embodied telescopically. In both FIGS. 4a and 4b the arrows indicate the mobility of the attachment elements 9 and the longitudinal convertibility of the reflective areas 4 and the dot-dash lines in FIG. 4b the original position of the respective reflective area 4. Here, it is clearly discernible that extending the attachment elements 9, on the one hand, leads to the angle of the reflective areas 4 changing in reference to the allocated solar modules 3, on the other hand, an additional reflective area 4 is formed by the attachment elements 9 themselves, in reference to a neighboring solar module 3, originally not allocated, therefore an even better utilization of the solar radiation occurs.

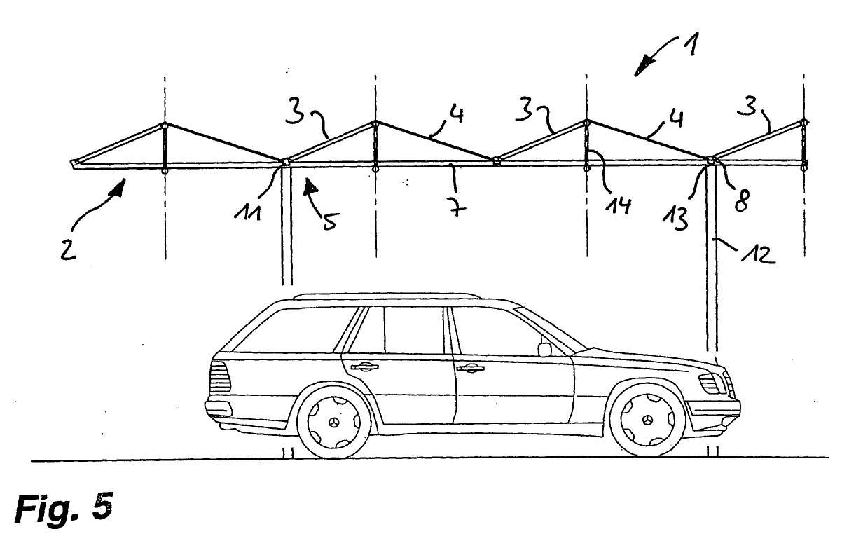

FIG. 5 shows a solar roof 1 with solar modules 3 and reflective areas 4 similar to FIG. 3, with in the figure the solar roof 1 being embodied as cladding of a carport. As already well discernible from the previous figures, a collector 11 for accepting and further transporting liquids wetting the roofing is provided at the bottoms of the gables formed by one solar module 3 and one reflective area 4 each. The collectors mentioned here form a grid of grooves crisscrossing the roofing and declining towards the drainage points 13. The drainage points 13 are here located at the tubular supports 12 for the girders 2, which support the solar roof at the base.

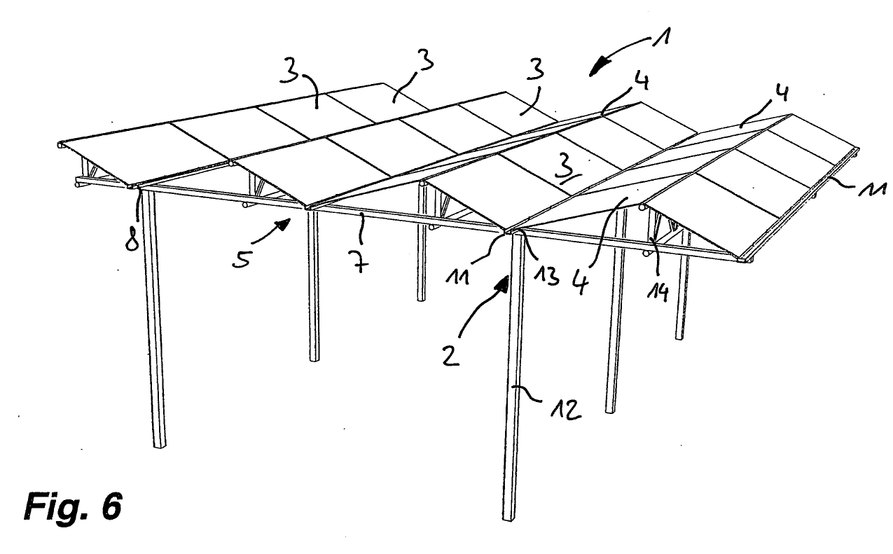

FIG. 6 shows the arrangement of the solar roof 1 as the carport of FIG. 1 in a perspective view from the rear.

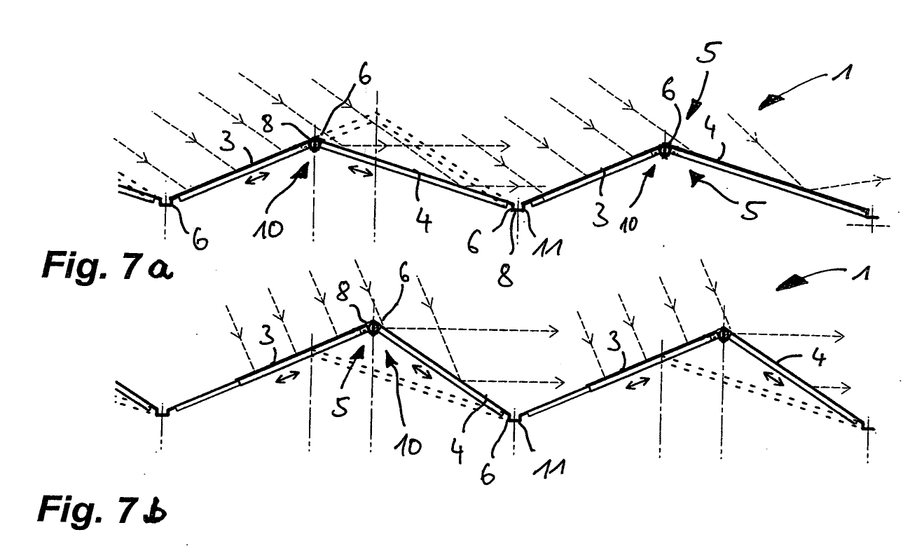

FIGS. 7a and 7b show an embodiment of the solar roof 1, which in turn comprises an alternating sequence of gables formed from solar modules 3 and reflective areas 4, with again the dot-dash lined arrows indicating the solar radiation and other positions of the solar modules 3 and the reflective areas 4 being indicated by dot-dash lines. The two arrows showing two arrow directions indicate the mobility of the telescopic solar modules 3 and the reflective areas 4 that can be modified telescopically in their length. The solar roof 1 can be transferred from a normal position, shown in FIG. 7a, in which the solar modules 3 and the reflective areas 4 form opposite, neighboring gables of approximately equal areas, via the adjustment means 10 arranged at the edge regions 5 into the position shown in FIG. 7b. Here, the reflective areas 4 are supported in an articulated fashion at the collector, adjust their angle in reference to the solar radiation, and telescopically reduce their area, while the solar modules 3 increase their area telescopically with their angle remaining unchanged, so that asymmetric gables develop. The reservoir 15, also arranged at the solar roof, the distribution system 16, as well as the recesses for the passage of liquids are not shown in greater detail, here.

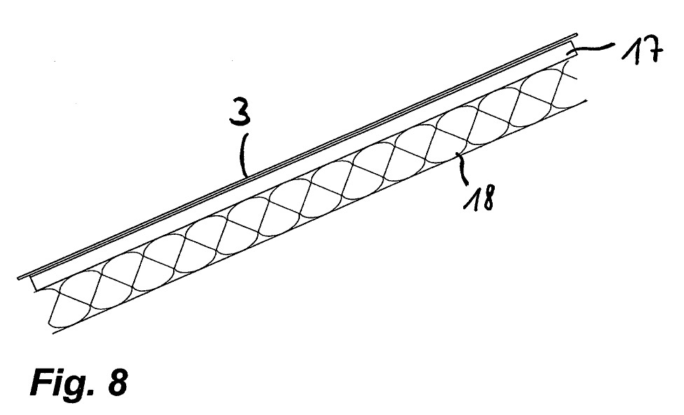

In FIG. 8 a solar module 3 is discernible, with a heat exchanger 17 being arranged at the side facing the base, not shown. The heat exchanger 17 is embodied as a planar storage element, which flush contacts the rear area of the solar module 3, resulting in a good heat exchange between the solar module 3 and the heat exchanger 17. Additionally, at the area of the heat exchanger 17 facing away from the solar module 3, an insulating layer is arranged in a planar fashion as an insulating agent 18. The inlet and outlet of the heat exchanger 17 is not shown.

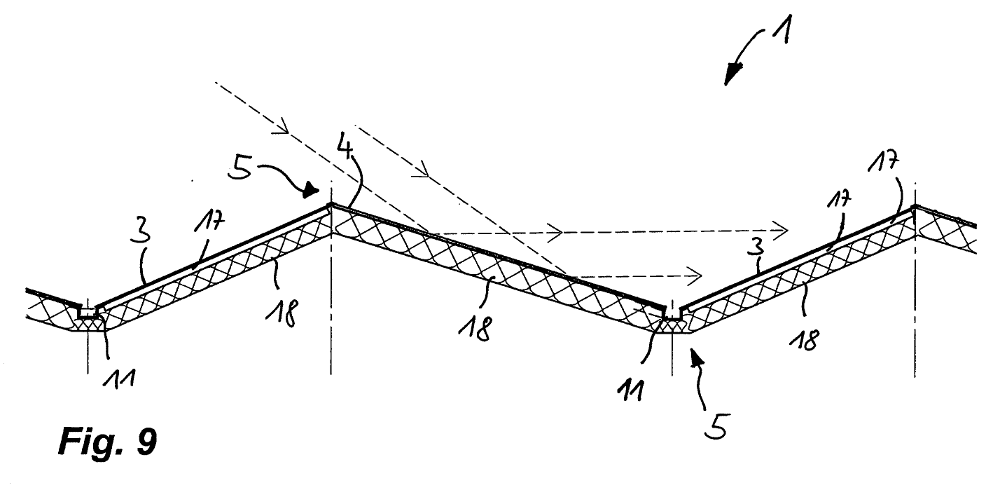

FIG. 9 shows a sequence of solar modules 3 and reflective areas 4 of a sealed, load-bearing solar roof 1, in which the solar modules of FIG. 8 are used. Accordingly, the heat exchangers 17 are arranged at the solar modules; additionally the insulating material 18 is discernible. In FIG. 9, one solar module 3 and one reflective area 4 each form a gable, with a groove-shaped collecting means 11 to accept liquids moistening the solar roof 1 being located at its eaves. In this solar roof, the cladding is essentially formed by alternating areas of solar modules 3 and reflective areas 4, alternating connected to each other, and each showing the same incline in reference to the base.

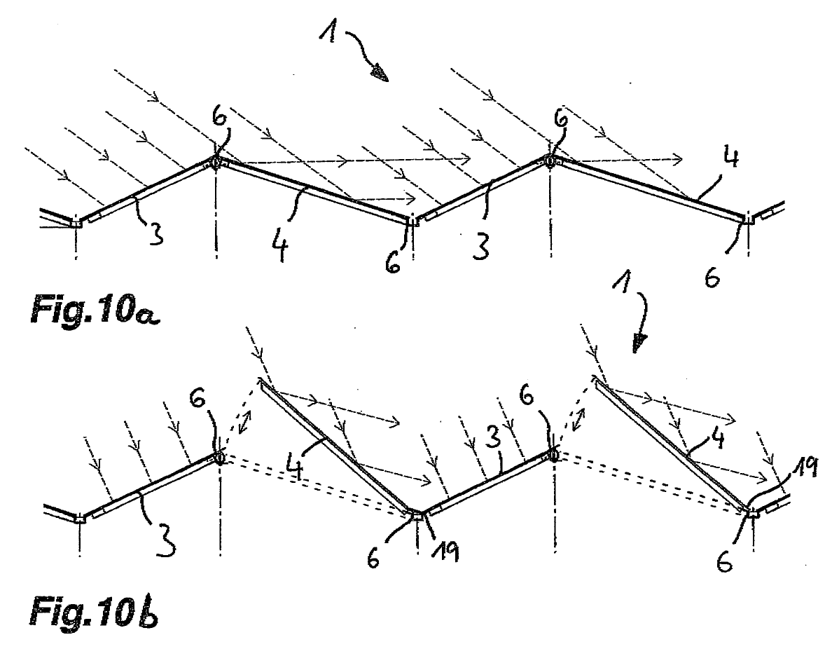

FIGS. 10a and 10b once more show an embodiment of the solar roof 1, which comprises an alternating sequence of gables formed by solar modules 3 and reflective areas 4, with the dot-dash lined arrows again indicating the solar radiation. Here, in FIG. 10a the solar roof 1 is shown in the closed state. Joints 6 are arranged between the solar modules 3 and the reflective areas 4. Due to the joints 6 the reflective areas 4 of this solar roof 1 are embodied articulate pivotal and the reflective area 4 can be separated from a joint 6 located at a ridge and can be pivoted at a joint 6, located at an eave, around a fixed edge 19 of the reflective area 4 in the direction of a neighboring solar module 3. This pivotal motion allows adjustment of the reflective area 4, with the radiation angle of the solar light being different from the one of FIG. 10b, is indicated by the double arrows. Additionally, this way ventilation is achieved of the volume located below the solar roof 1. The position of the reflective area 4 of FIG. 10a is embodied in dot-dash lines in FIG. 10b.

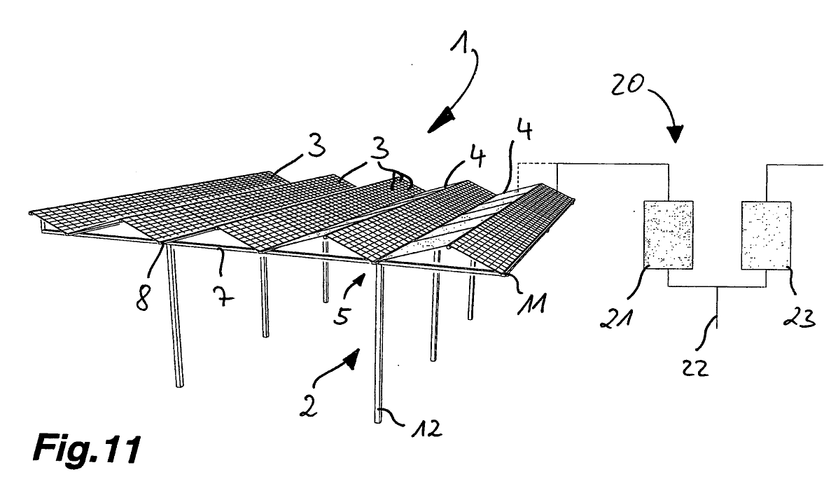

FIG. 11 finally shows a similar embodiment of the solar roof 1 as in FIG. 6, however, here the roof elements are not articulate. The gables of the solar roof 1 are formed in a lateral extension as a sequence of areas of solar modules 3 and reflective areas 4, so that in the longitudinal extension oblong, continuous gable areas of the same type are formed. The areas of the solar modules are here each formed from an equal number of regularly arranged solar modules 3. At the right side of FIG. 11 for the viewer, schematically a controller 20 is shown, which illustrates the possibility of reverse arrangement of the solar modules 3 and, perhaps, the reflective areas, indicated in dot-dash lines. The controller 20 is provided with an inverter 21, allowing to feed the power to an electric outlet 22 as well as to draw it therefrom. When drawing power, it can be used for example to heat the solar modules 3. A consumer 23 can be supplied both by the power created by the solar roof 1 as well as by electricity from the electric outlet 22.

The present invention therefore relates to a solar roof 1 to roof over a base area or a volume built with a girder system 2, which is provided with one or more planar solar modules 3, allocated to a solar power plant, and with at least one reflective area 4, allocated at an angle in reference to the solar module or modules 3 and additional roof elements, if necessary. In order to provide a solar roof 1 with good effectiveness, which can be used for roofing over an essentially arbitrary base area without major difficulties in adjustment at reduced costs and low assembly expenses, it may be provided, among other things, that the solar module or modules 3 are interconnected at their edge regions 5 and/or connected to the reflective area or areas 4 as well as both of them with optional roof elements provided such that the solar roof 1 forms a tight, sealed roof cladding in the form of a continuous area and that the solar roof 1 is provided as a load-bearing roof construction.

1. A solar roof for roofing over a base area or a built volume, the solar roof comprises at least one solar module allocated to a solar energy plant and at least one reflective area, arranged at an angle in reference to the at least one solar module, the at least one solar module (3) is interconnected at edge regions (5) thereof or connected to the at least one reflective area (4) as well as additional roof elements such that the solar roof (1) forms a closed, sealed roof cladding for a continuous area and the solar roof (1) is provided as a load-bearing roof construction.

2. A solar roof according to claim 1, further comprises a girder system (2) or a support device, which supports at least a portion of the solar roof (1) at least at points.

3. A solar roof according to claim 1, wherein at least one heat exchanger (17) is provided for least one of the at least one solar module (3) or the at least one reflective area (4) in a detachable fashion or integrated, by which a temperature of the at least one of solar module (3) or the reflective area (4) can be changed locally in a region of the mounting.

4. A solar roof according to claim 3, wherein the heat exchanger is embodied as a planar storage element, arranged at a side of the at least one of solar module (3) or the at least one of reflective area (4) facing the base area.

5. A solar roof according to claim 4, wherein the heat exchanger (17) is provided with an inlet and an outlet and forms a part of an unpressurized storage circuit, comprising a reservoir.

6. A solar roof according to claim 1, wherein at least one of the solar modules (3) or at least one of the reflective areas (4) of the solar roof (1) are arranged at a joint (6), and can articulate around a respective fixed edge (19) in a direction of at least one of a neighboring reflective area (4) or a neighboring solar module (3).

7. A solar roof according to claim 6, wherein in a region of the at least one of the solar module (3) or the reflective area (4) that can articulate or in a region of the supportive structure (2), at least one adjuster (10) is provided for moving the solar module or the reflective area.

8. A solar roof according to claim 7, wherein at least one attachment element (9) is arranged in a region of a free end of the reflective area (4) or in an edge region of the solar module (3) neighboring the free end, which can be transferred from a normal position, in which it projects into the built volume, into one or more extended positions gradually or telescopically, such that it forms a part of the roof cladding.

9. A solar roof according to claim 1, further comprising at least one of a moisture or liquid sensor to determine a potential moistening of an area of the solar roof (1).

10. A solar roof according to claim 8, wherein at least one collector (11) is provided at the edge regions (5) of at least one of the at least one solar module (3) or the at least one reflective area (4) or additional roof elements, in the edge regions (5) neighboring the solar roof (1), to accept and forward liquids moistening the roof.

11. A solar roof according to claim 10, wherein the collector (11) is formed by a web of grooves, crisscrossing the roofing and declining towards drainage points (13).

12. A solar roof according to claim 11, wherein at least one support tube or hollow profile is provided that supports the solar roof (1) or a girder system (2) that supports the solar roof.

13. A solar roof according to claim 12, wherein the drainage points (13) are arranged at ends of the at least one support tube or hollow profile (12) facing the solar roof (1).

14. A solar roof according to claim 1, wherein a distribution system (16) is provided to supply liquids at one or more gables or eaves of gables or a main gable of the solar roof.

15. A solar roof according to claim 11, wherein the collector (11) comprises a connection to a storage circuit for heat exchange liquid for at least one heat exchanger provided for at least one of the at least one solar module (3) or the at least one reflective area (4).

16. A solar roof according to claim 1, further comprising a controller (20) connected to the at least one solar module (3) to control feeding to and/or drawing of power from a grid.

17. A solar roof according to claim 1, wherein several of the solar modules (3) or the reflective areas (4) are connected to each other at an angle and form a predominant area of a side of a roof gable or a pitched side of the solar roof (1).

18. A solar roof according to claim 17, wherein the roof cladding is formed by alternating areas of solar modules (3) and reflective areas (4), connected to each other, with each having a same incline with regard to the base area.

19. A solar roof according to claim 1, wherein a sequence of the solar modules (3) and the reflective areas (4), connected at an angle and forming gables, cover a predominant part of a side of a pitched roof.

20. A solar roof according to claim 19, wherein in that in a plane view, ridges of a series of gables extend essentially perpendicular in reference to a ridge of the gable of the solar roof (1).

21. A solar roof according to claim 20, wherein at least one of the solar modules (3) or the reflective areas (4) comprise elements of transparent, partially transparent, partially or fully reflective materials.

22. A solar roof according to claim 1, wherein an insulating material (10) is arranged between at least one of the solar modules (3) or the reflective areas (4) and the built volume covered by the solar roof.

23. A solar roof according to claim 1, wherein at least one of the solar modules (3) or the reflective areas (4) can be longitudinally adjusted.

24. A solar roof according to claim 23, wherein the longitudinal adjustment is to various sizes of the base area in at least one direction of its extension.
